(19) United States
(12) Patent Application Publication
(10) Pub. No.: US 2024/0379385 A1
(43) Pub. Date: Nov. 14, 2024

(54) WAFER CONVEYANCE DEVICE

(71) Applicant: Hitachi High-Tech Corporation, Tokyo (JP)

(72) Inventors: Katsutoshi KOBAYASHI, Tokyo (JP); Akira NISHIOKA, Tokyo (JP); Tomokazu KOBAYASHI, Tokyo (JP); Masashi FUJITA, Tokyo (JP); Toshihiko SHIMIZU, Tokyo (JP); Itsuro SAWADA, Tokyo (JP)

(73) Assignee: Hitachi High-Tech Corporation, Tokyo (JP)

(21) Appl. No.: 18/645,006

(22) Filed: Apr. 24, 2024

(30) Foreign Application Priority Data
May 10, 2023 (JP) 2023-078103

(51) Int. Cl. H01L 21/67; F25B 21/02; F28D 1/02; F28D 21/00

(52) U.S. Cl. CPC H01L 21/67017; F25B 21/02; F25B 2321/023; F28D 2021/0078

(57) ABSTRACT

Provided is a wafer conveyance device that suppresses a temperature rise of gas in a wafer conveyance chamber. A wafer conveyance device for conveying a wafer between a FOUP (Front-Opening Unified Pod) in which the wafer is stored and a processing device for processing the wafer, the wafer conveyance device including a wafer conveyance chamber in which a conveyance robot is installed, an FFU chamber communicating with the wafer conveyance chamber, a return duct provided in a wall or a door of the wafer conveyance chamber and communicating with both the wafer conveyance chamber and the FFU room, a blowing fan that blows gas from the FFU chamber into the wafer conveyance chamber, and a heat exchanger that cools the gas circulating in an internal space including the FFU chamber, the return duct, and the wafer conveyance chamber.

### CLAIM OF PRIORITY

The present application claims priority from Japanese Patent application serial no. 2023-78103, filed on May 10, 2023, the content of which is hereby incorporated by reference into this application.

### Technical Field

The present invention relates to a wafer conveyance device incorporating a heat exchanger.

### Background Art

The wafer conveyance device is a device that conveys wafers stored in a FOUP (Front-Opening Unified Pod) to a processing device that processes the wafers. Specifically, the wafer conveyance device has a conveyance robot in the wafer conveyance chamber, and conveys the wafer between the FOUP and the processing device by the conveyance robot. Then, in the wafer conveyance device, an FFU (fan filter unit) is installed on the upper side of the wafer conveyance chamber, and gas is blown by the FFU to the wafer in the wafer conveyance chamber so that impurities do not adhere to the wafer. Such a wafer conveyance device is described in PTL 1 and PTL 2.

In the abstract of PTL 1, there is a description of “In the conveyance chamber 1 which is an EFEM device for transferring an object to be transferred to and from the processing device side using the conveyance robot 2 in the housing, the housing 3 has a conveyance space S11 for accommodating the conveyance robot 2, a gas processing space S2 for accommodating a gas processing device (organic substance removal filter 71, acid removal filter 72, and alkali removal filter 73), and a gas return space S12 capable of returning gas from the conveyance space to the gas processing space. The conveyance space, the gas processing space, and the gas return space communicate with each other to form one sealed space to form the circulation path CL, and the plurality of fans 74 to 77 are provided in the circulation path to form a circulation flow.”

Further, in PTL 2, there is a description in paragraph 0028 of “The ventilation unit drive chamber 110 includes a main fan 140. The main fan 140 blows air (or nitrogen gas) downward . . . . Air flows from the ventilation unit drive chamber 110 to the FOUP receiving chamber 120.” There is a description in paragraph 0032 of “The ventilation duct 150 connects the FOUP receiving chamber 120 and the ventilation unit drive chamber 110.” There is a description in paragraph 0046 of “In the substrate conveyance devices 200, 300, and 400 according to the present invention, air circulates only to the FOUP receiving chamber 120.”

### CITATION LIST

### Patent Literature

PTL 1: JP 2021-7172 A

PTL 2: JP 2021-34724 A

### SUMMARY OF INVENTION

### Technical Problem

However, in the wafer conveyance devices described in PTLs 1 and 2, since the gas is circulated in the sealed and closed wafer conveyance chamber, there is a problem that the power consumption of the fan or the power consumption of the conveyance robot serves as a heat source and the temperature of the gas rises. Furthermore, when the wafer heated by the gas whose temperature has increased is conveyed to the processing device, there is a problem that the processing time in the processing device is prolonged.

Therefore, an object of the present invention is to provide a wafer conveyance device that suppresses a temperature rise of gas in a wafer conveyance chamber.

### Solution to Problem

In order to solve the above problems, a wafer conveyance device of the present invention is a wafer conveyance device for conveying a wafer between a FOUP (Front-Opening Unified Pod) in which the wafer is stored and a processing device for processing the wafer. The wafer conveyance device includes: a wafer conveyance chamber in which a conveyance robot is installed; an FFU chamber communicating with the wafer conveyance chamber; a return duct provided in a wall or a door of the wafer conveyance chamber and communicating with both the wafer conveyance chamber and the FFU room; a blowing fan that blows gas from the FFU chamber into the wafer conveyance chamber; and a heat exchanger that cools the gas circulating in an internal space including the FFU chamber, the return duct, and the wafer conveyance chamber.

### Advantageous Effects of Invention

According to the present invention, it is possible to provide a wafer conveyance device that suppresses a temperature rise of gas in a wafer conveyance chamber.

### BRIEF DESCRIPTION OF DRAWINGS

FIG. 1 is an overall view of a wafer conveyance device E.

FIG. 2 is a cross-sectional view taken along line A-A of FIG. 1 in a first embodiment.

FIG. 3 is a perspective view of a wafer conveyance chamber.

FIG. 4 is a diagram illustrating a cooling heat sink having an integral structure with a ceiling wall of an FFU chamber according to the first embodiment.

FIG. 5 is a configuration diagram of a wafer conveyance device in a second embodiment.

FIG. 6 is a configuration diagram of a wafer conveyance device in a third embodiment.

FIG. 7A is a diagram illustrating an example of a configuration of a wafer conveyance device in a fourth embodiment.

FIG. 7B is a diagram illustrating another example of the configuration of the wafer conveyance device in the fourth embodiment.

FIG. 7C is a diagram illustrating another example of the configuration of the wafer conveyance device in the fourth embodiment.

FIG. 8A is a diagram illustrating an example of a configuration of a wafer conveyance device in a fifth embodiment.

FIG. 8B is a diagram illustrating another example of the configuration of the wafer conveyance device in the fifth embodiment.

FIG. 8C is a diagram illustrating another example of the configuration of the wafer conveyance device in the fifth embodiment.

FIG. 8D is a diagram illustrating another example of the configuration of the wafer conveyance device in the fifth embodiment.

FIG. 9A is a diagram illustrating an example of a configuration of a wafer conveyance device in a sixth embodiment.

FIG. 9B is a diagram illustrating another example of the configuration of the wafer conveyance device in the sixth embodiment.

FIG. 10A is a diagram illustrating an example of a configuration of a wafer conveyance device in a seventh embodiment.

FIG. 10B is a diagram illustrating another example of the configuration of the wafer conveyance device in the seventh embodiment.

FIG. 11 is a configuration diagram of a cooling unit in an eighth embodiment.

FIG. 12 is a configuration diagram of a cooling unit in a ninth embodiment.

FIG. 13 is a diagram for explaining a method of fixing a cooling unit in a tenth embodiment.

FIG. 14 is a diagram for explaining a method of fixing a cooling unit in an eleventh embodiment.

FIG. 15 is a diagram for explaining a method of fixing a cooling unit in a twelfth embodiment.

### DESCRIPTION OF EMBODIMENTS

Hereinafter, the present invention will be described in detail with reference to the drawings. The present invention is not limited to the embodiments described below. These embodiments are merely examples, and the present invention can be implemented in various modified and improved forms based on the knowledge of those skilled in the art. In the drawings used in the following description, common devices and machines are denoted by the same reference numerals, and the description of the devices, machines, and operations described above may be omitted.

### First Embodiment

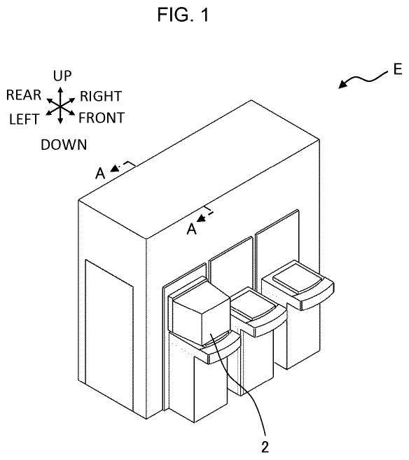

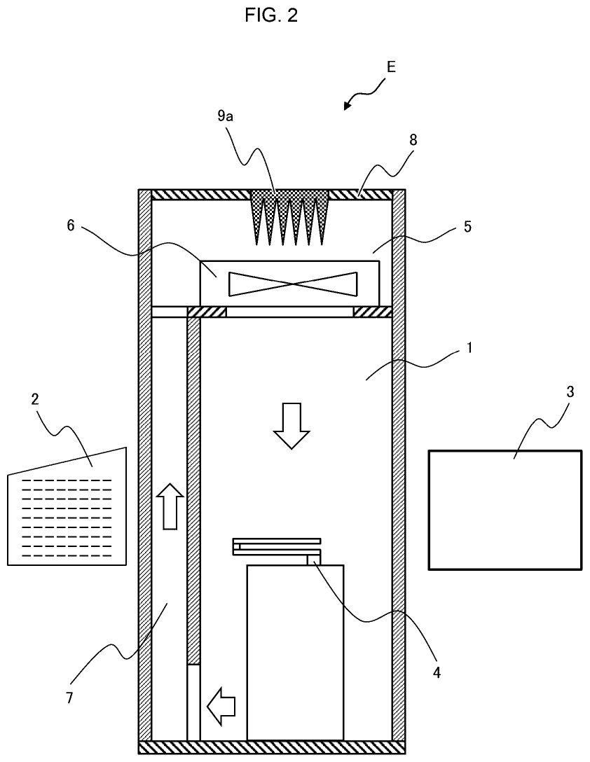

FIG. 1 is an overall view of a wafer conveyance device E. FIG. 2 is a cross-sectional view taken along line A-A of FIG. 1. As illustrated in FIG. 2, a FOUP 2 is located in front of the wafer conveyance device E, and a processing device 3 is located behind the wafer conveyance device E. In a wafer conveyance chamber 1, a conveyance robot 4 that takes out the wafers stored in the FOUP 2 and conveys the wafers to the processing device 3 that processes the wafers is installed. The conveyance robot 4 also takes out the wafer processed by the processing device 3 from the processing device 3 and returns the wafer to the FOUP 2. An FFU chamber 5 communicating with the wafer conveyance chamber 1 is provided above the wafer conveyance chamber 1, and an FFU 6 provided with a blowing fan for blowing gas from the FFU chamber 5 into the wafer conveyance chamber 1 is provided in the FFU chamber 5.

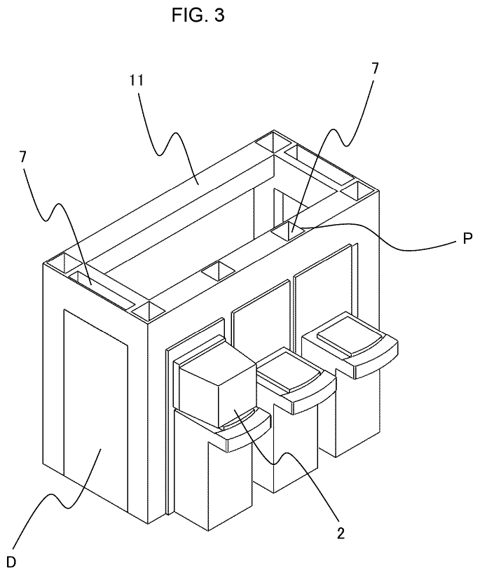

The wafer conveyance device E includes a return duct 7 communicating with both the wafer conveyance chamber 1 and the FFU chamber 5. FIG. 3 is a perspective view of the wafer conveyance chamber 1. The return duct 7 is formed as a ventilation path through which gas passes by making a column P in the wafer conveyance chamber 1 hollow. In addition, for example, as illustrated in FIG. 3, the return duct 7 may be formed by making a door D for allowing a person to enter and leave the wafer conveyance chamber 1 and a wall on an upper side thereof hollow. In addition, the return duct 7 may be formed in a wall 11 of the wafer conveyance chamber 1. In the present embodiment, the return duct 7 provided on the column P will be described.

As illustrated in FIG. 2, the wafer conveyance device E is hermetically sealed, and gas circulates inside the wafer conveyance device E. Specifically, the gas injected into the FFU chamber 5 is sent to the wafer conveyance chamber 1 by the FFU 6. Then, the gas blown into the wafer conveyance chamber 1 is returned to the FFU chamber 5 through the return duct 7. That is, the gas circulates in the internal space constituted by the FFU chamber 5, the return duct 7, and the wafer conveyance chamber 1.

The wafer conveyance device E includes a heat exchanger that cools the gas circulating in the internal space. The heat exchanger is installed where a gas flow is generated. Examples of the heat exchanger include a cooling heat sink.

In the FFU chamber 5, the gas that has returned to the FFU chamber 5 through the return duct 7 is sent to the wafer conveyance chamber 1 by the FFU 6. Therefore, an airflow is generated near the inlet of the FFU 6. Therefore, as illustrated in FIG. 2, a cooling heat sink 9a is installed near the inlet of the FFU 6. By installing the cooling heat sink 9a in this manner, the circulating gas comes into contact with the cooling heat sink 9a and is cooled, and a temperature rise in the wafer conveyance device can be suppressed. The cooling heat sink 9a is preferably installed at a place where the speed of the circulating gas flow is high.

As the gas, an inert gas such as a nitrogen gas or air containing oxygen or the like can be used. In any case, since the temperature is lowered by being cooled by the heat exchanger such as the cooling heat sink 9a, it is possible to suppress the temperature rise in the wafer conveyance device. In addition, in the case of an inert gas, adhesion of impurities to the wafer can be prevented.

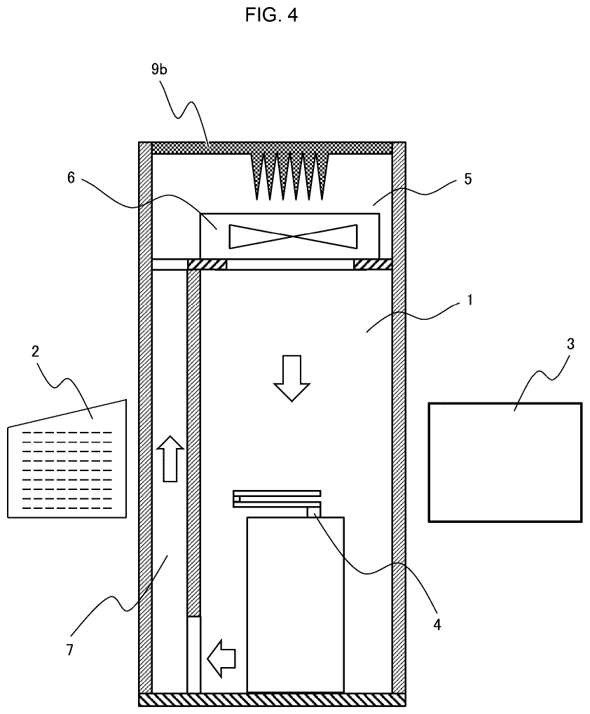

FIG. 4 is a diagram illustrating a cooling heat sink 9b having an integral structure with a ceiling wall 8 of the FFU chamber 5. In FIG. 2, the ceiling wall 8 of the FFU chamber 5 and the cooling heat sink 9a are made of different materials. For example, stainless steel is used for the ceiling wall 8 of the FFU chamber 5, and aluminum is used for the cooling heat sink 9a. On the other hand, in FIG. 4, the cooling heat sink 9b having an integral structure with the ceiling wall of the FFU chamber 5 is used. In the case of the configuration of FIG. 4, since the portion up to the ceiling wall 8 of FIG. 2 is made of a material having good thermal conductivity such as aluminum, heat is easily released to the outside, and the temperature rise in the wafer conveyance device E can be further suppressed.

### Second Embodiment

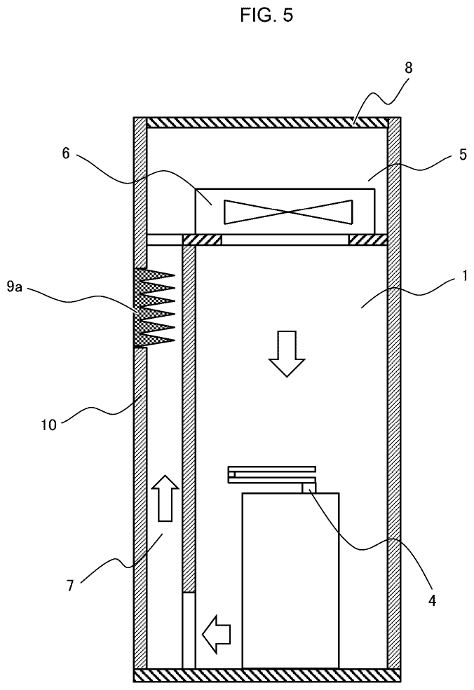

FIG. 5 illustrates a configuration of the wafer conveyance device E in a second embodiment. In the wafer conveyance device E in the second embodiment, the position of the cooling heat sink 9a is different from that in the first embodiment. Specifically, as illustrated in FIG. 5, the wafer conveyance device E of the present embodiment includes the cooling heat sink 9a in the return duct 7, for example, in a wall 10 of the return duct 7. The speed of the gas flow is high in the return duct 7. Therefore, by placing the cooling heat sink 9a on the return duct 7, heat exchange between the cooling heat sink 9a and the gas is promoted, and the temperature rise of the gas can be suppressed. As a result, the temperature rise in the wafer conveyance device E can be suppressed. Similarly, when the return duct 7 is provided in the door D or the wall 11 of the wafer conveyance chamber, the temperature rise in the wafer conveyance device E can be suppressed by installing the cooling heat sink 9a in the return duct 7.

### Third Embodiment

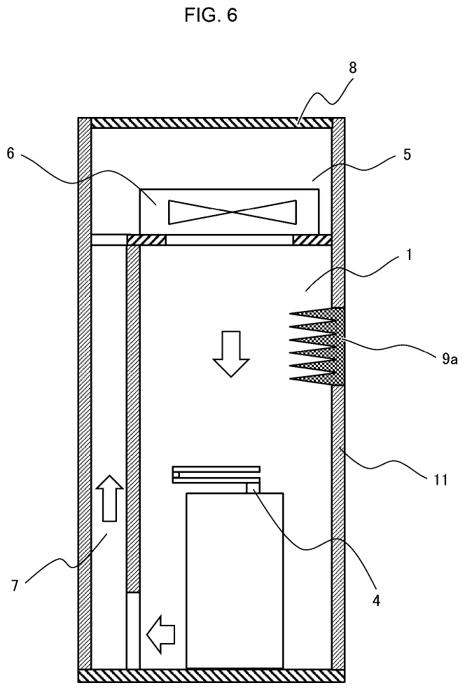

FIG. 6 illustrates a configuration of a wafer conveyance device E in a third embodiment. In the wafer conveyance device E in the third embodiment, the position of the cooling heat sink 9a is different from that in the first embodiment. Specifically, as illustrated in FIG. 6, the wafer conveyance device E of the present embodiment includes a cooling heat sink 9a in the wall 11 of the wafer conveyance chamber 1 so as to be located immediately below the FFU 6 in the wafer conveyance chamber 1. Since the gas is blown out from the FFU 6 immediately below the FFU 6, the speed of the airflow is high. Therefore, by placing the cooling heat sink 9a immediately below the FFU 6, heat exchange between the cooling heat sink 9a and the gas is promoted, and the temperature rise of the gas can be suppressed. As a result, the temperature rise in the wafer conveyance device E can be suppressed.

### Fourth Embodiment

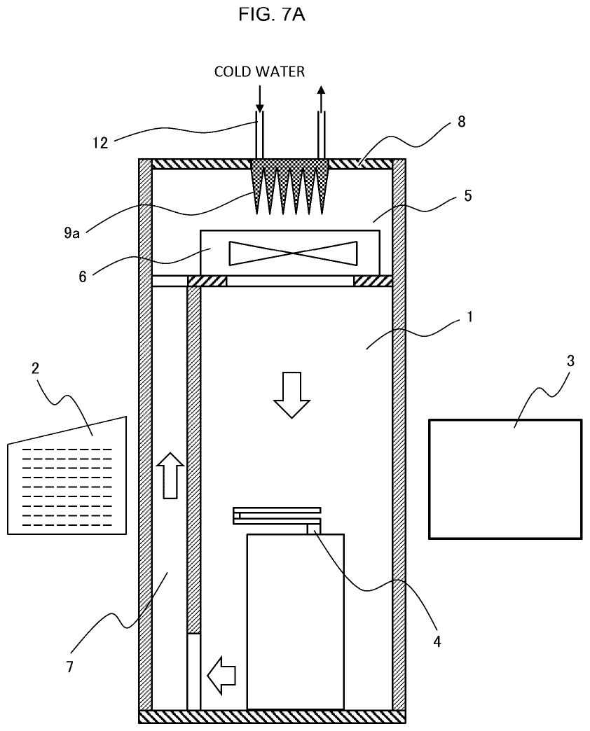

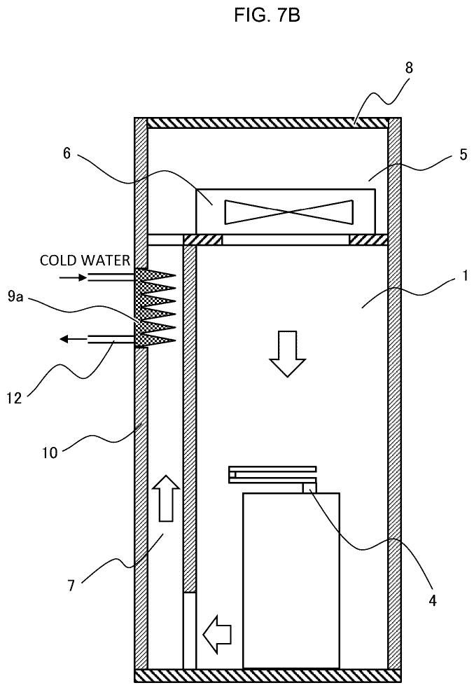

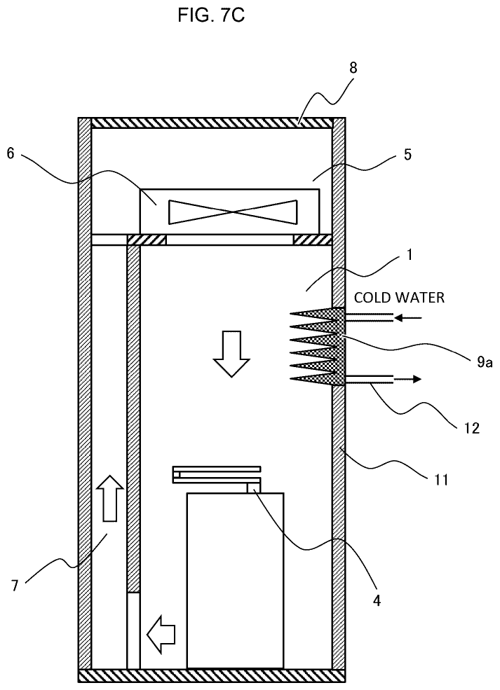

FIGS. 7A to 7C illustrate configurations of a wafer conveyance device in a fourth embodiment. The wafer conveyance device E in the fourth embodiment is an example in which the cooling heat sinks of the first to third embodiments include a cold water pipe. Hereinafter, differences from the first to third embodiments will be mainly described.

FIG. 7A is a diagram illustrating a configuration in which the cooling heat sink 9a is installed in the ceiling wall 8 of the FFU chamber 5. FIG. 7B is a diagram illustrating a configuration in which the cooling heat sink 9a is installed in the return duct 7. FIG. 7C is a diagram illustrating a configuration in which the cooling heat sink 9a is installed immediately below the FFU 6 in the wafer conveyance chamber 1.

The cooling heat sink 9a illustrated in FIGS. 7A to 7C incorporates a cold water pipe 12 through which a low-temperature liquid, for example, cold water flows. As a result, the cooling heat sink 9a is cooled, and the heat of the gas is taken away, and the temperature rise of the wafer conveyance device can be suppressed. Even when a fin tube such as a radiator is used instead of the cooling heat sink 9a, the same effect can be obtained. Since the cold water flows in the tube incorporated in the radiator, the fin is cooled and the heat of the gas can be taken away.

According to the present embodiment, since the cooling heat sink 9a is cooled by the cold water pipe, the gas in contact with the cooling heat sink 9a can be cooled. Instead of the cooling heat sink 9a including the cold water pipe, a fin tube or the like incorporating a cold water pipe represented by a radiator can also be used.

### Fifth Embodiment

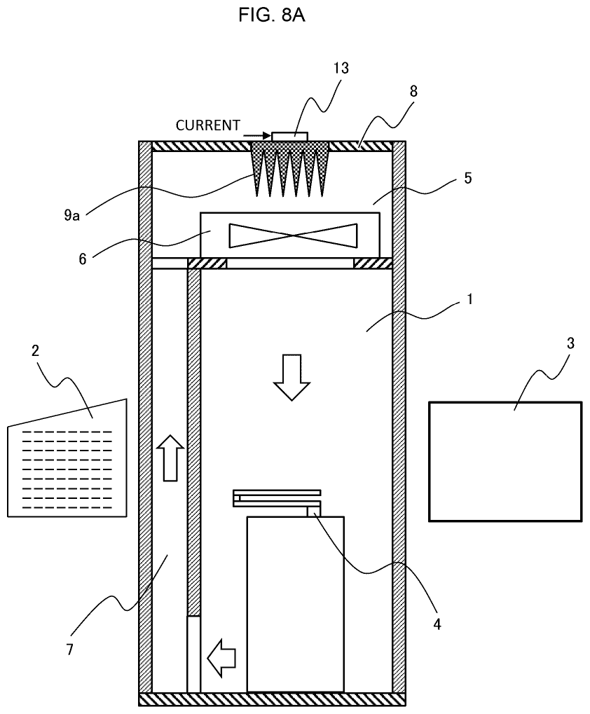

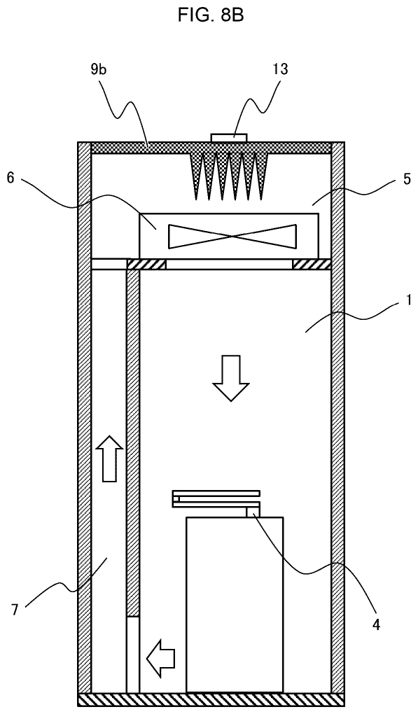

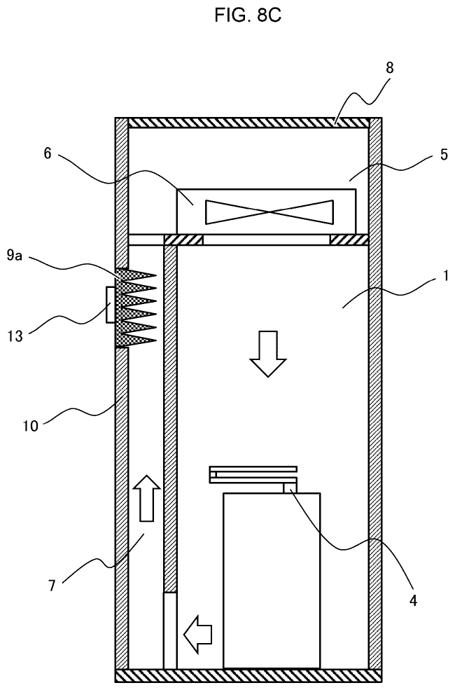

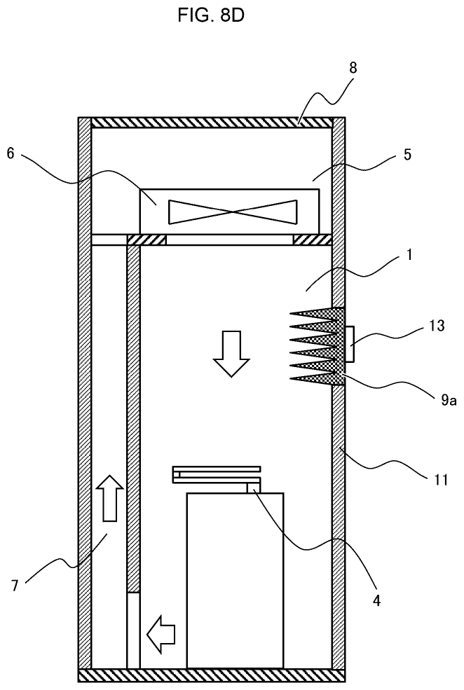

FIGS. 8A to 8D illustrate a configuration of a wafer conveyance device E in a fifth embodiment. The wafer conveyance device E in the fifth embodiment includes a Peltier element 13 that cools the cooling heat sinks 9a and 9b of the first to third embodiments. Hereinafter, differences from the first to third embodiments will be mainly described.

FIG. 8A is a diagram illustrating a configuration in which the cooling heat sink 9a is installed in the ceiling wall 8 of the FFU chamber 5. FIG. 8B is a diagram illustrating a configuration including a cooling heat sink 9b integrated with the ceiling wall 8 of the FFU chamber. FIG. 8C is a diagram illustrating a configuration in which the cooling heat sink 9a is installed in the return duct 7. FIG. 8D is a diagram illustrating a configuration in which the cooling heat sink 9a is installed immediately below the FFU 6 in the wafer conveyance chamber 1.

As illustrated in FIGS. 8A to 8D, in the wafer conveyance device E of the fifth embodiment, the Peltier element 13 is installed on the heat dissipation surface of the cooling heat sink 9a, and the low-temperature surface of the Peltier element 13 adheres to the heat dissipation surface of the cooling heat sink. The cooling heat sinks 9a and 9b are cooled by applying current to the Peltier element 13. As a result, the cooling heat sinks 9a and 9b are cooled, and the heat of the gas is taken away, and the temperature rise of the gas can be suppressed. As a result, the temperature rise in the wafer conveyance device E can be suppressed.

### Sixth Embodiment

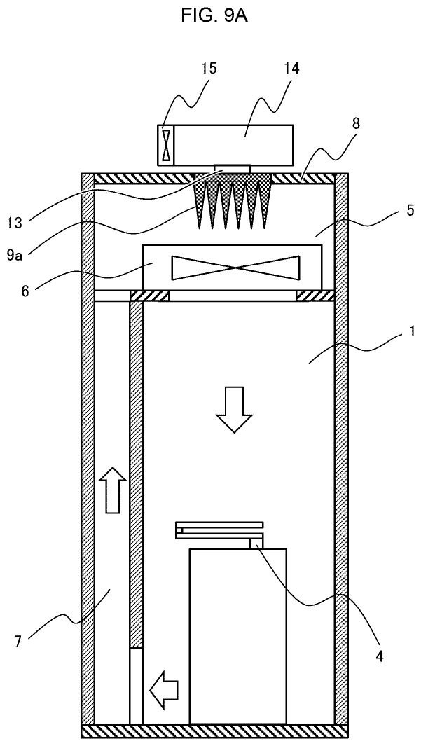

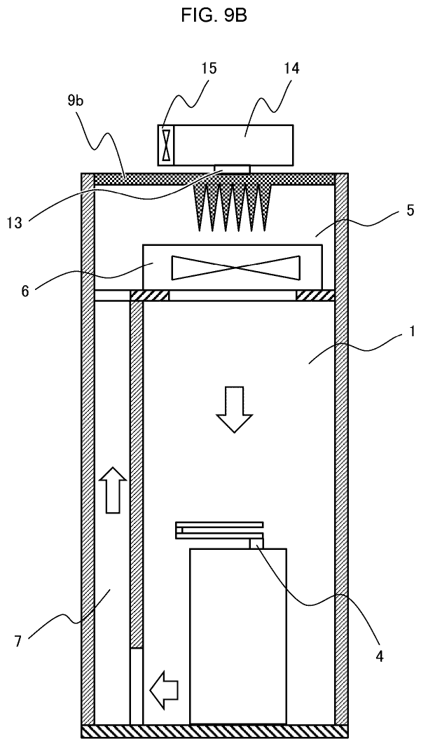

FIGS. 9A and 9B illustrate a configuration of a wafer conveyance device in a sixth embodiment. The wafer conveyance device E in the sixth embodiment includes a heat dissipation heat sink 14 and a cooling fan 15 for dissipating heat of a Peltier element in addition to the configurations of FIGS. 8A and 8B of the fifth embodiment. Hereinafter, differences from the fifth embodiment will be mainly described.

FIG. 9A is a diagram illustrating a configuration in which the cooling heat sink 9a is installed in the ceiling wall 8 of the FFU chamber 5. FIG. 9B is a diagram illustrating a configuration including a cooling heat sink 9b integrated with the ceiling wall 8 of the FFU chamber. A Peltier element 13 is installed outside the cooling heat sinks 9a and 9b. When a current flows through the Peltier element 13, a low-temperature surface and a high-temperature surface are formed. By bonding the low-temperature surface to the cooling heat sinks 9a and 9b, the cooling heat sinks can be cooled. Here, if the heat of the high-temperature surface is not dissipated, the cooling performance of the Peltier element may be deteriorated. Therefore, the heat dissipation heat sink 14 is bonded to the high-temperature surface of the Peltier element 13, and the cooling fan 15 for cooling the heat dissipation heat sink 14 is provided in the heat dissipation heat sink 14. With this structure, the cooling performance of the Peltier element is improved, and the cooling heat sinks 9a and 9b can be further cooled.

### Seventh Embodiment

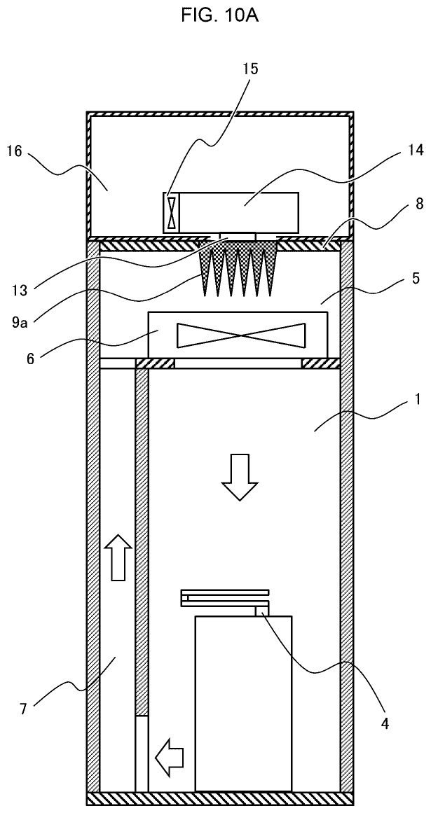

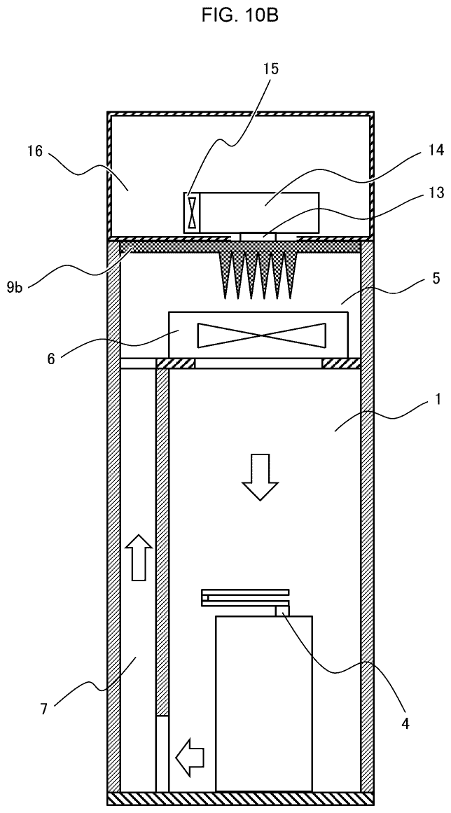

FIGS. 10A and 10B illustrate a configuration of a wafer conveyance device in a seventh embodiment. The wafer conveyance device E according to the seventh embodiment includes, in addition to the configuration of the sixth embodiment, an electrical compartment 16 in which electrical components (power supply-related components, drivers of the conveyance robot 4, and the like) are stored on the FFU chamber 5. Hereinafter, differences from the sixth embodiment will be mainly described.

FIG. 10A is a diagram illustrating a configuration in which the cooling heat sink 9a is installed in the ceiling wall 8 of the FFU chamber 5. FIG. 10B is a diagram illustrating a configuration including a cooling heat sink 9b integrated with the ceiling wall 8 of the FFU chamber. In both FIGS. 10A and 10B, the Peltier element 13, the heat dissipation heat sink 14, and the cooling fan 15 are provided in the electrical compartment 16 above the FFU chamber 5.

In the wafer conveyance device E including the electrical compartment 16, the Peltier element 13, the heat dissipation heat sink 14, and the cooling fan 15 can be provided without increasing the overall size by effectively utilizing the space of the electrical compartment 16.

### Eighth Embodiment

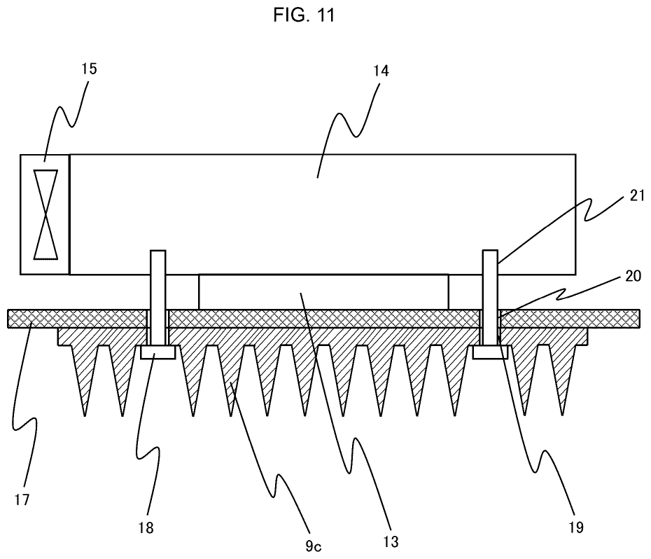

FIG. 11 illustrates a configuration diagram of a cooling unit of an eighth embodiment. The cooling unit is a mechanism for cooling the gas in the sixth and seventh embodiments, and includes a cooling heat sink 9c, a Peltier element 13, a heat dissipation heat sink 14, and a cooling fan 15. The cooling unit further includes a flat plate 17 sandwiched between the cooling heat sink 9c and the low-temperature surface of the Peltier element 13. Through-holes 19 and 20 for passing bolts 18 are formed in the cooling heat sink 9a and the flat plate 17, respectively. A screw hole 21 into which the bolt 18 is inserted is machined in the heat dissipation heat sink 14. By inserting and tightening the bolt 18 from the cooling heat sink 9a side, the Peltier element 13, the heat dissipation heat sink 14, and the flat plate 17 are integrally fixed, and the Peltier element 13 can be sandwiched between the flat plate 17 and the heat dissipation heat sink 14. As a result, the degree of adhesion between the low-temperature surface of the Peltier element 13 and the flat plate 17 increases, and the flat plate 17 can be further cooled. Since the cooled flat plate 17 comes into contact with the cooling heat sink 9a, the cooling heat sink 9a can be further cooled by the flat plate 17. In addition, by tightening the bolt 18, the degree of adhesion between the high-temperature surface of the Peltier element 13 and the heat dissipation heat sink 14 increases, and the heat of the Peltier element 13 can be further dissipated.

### Ninth Embodiment

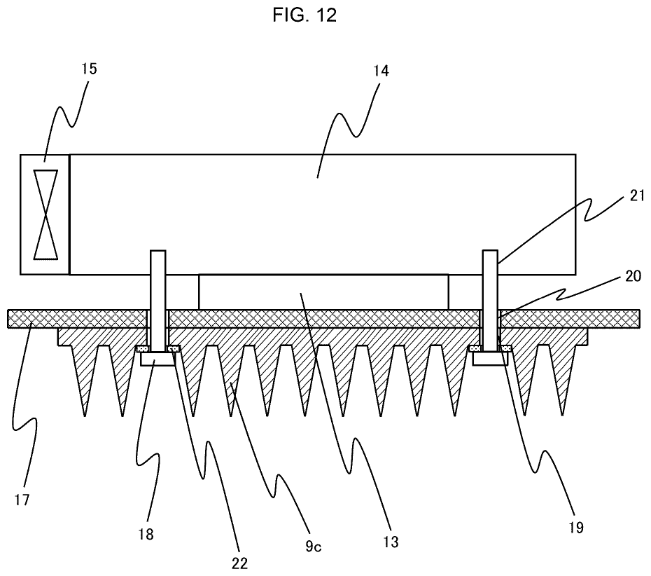

FIG. 12 is a configuration diagram of a cooling unit of a ninth embodiment. The cooling unit of the present embodiment includes, in addition to the configuration of the eighth embodiment, a material having high thermal resistance, for example, a resin material 22 sandwiched between the cooling heat sink 9a and the head of the bolt 18. This makes it possible to prevent the heat of the heat dissipation heat sink 14 from being transferred to the cooling heat sink 9a via the bolt 18.

### Tenth Embodiment

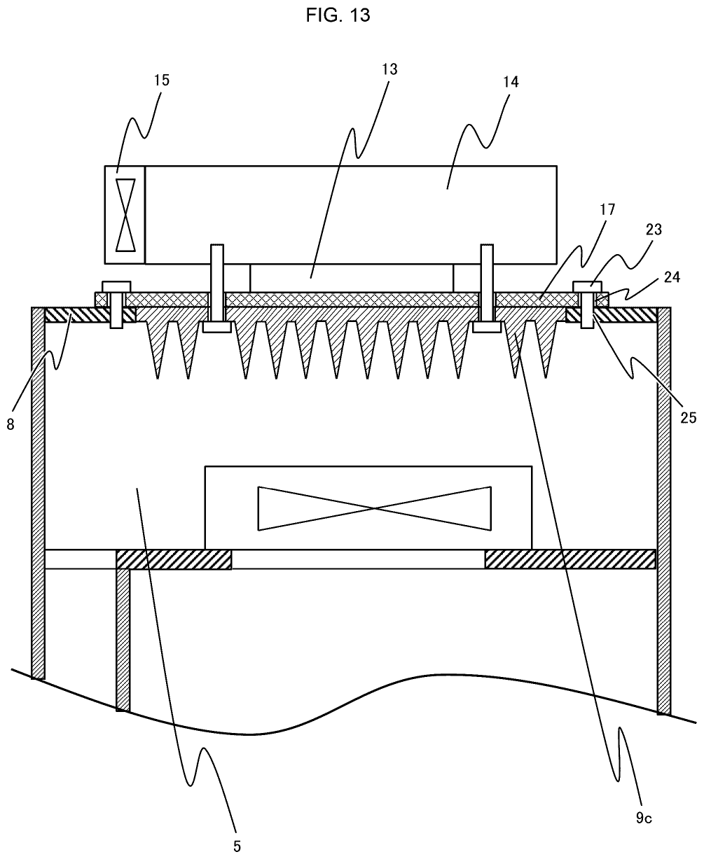

FIG. 13 is a diagram for explaining a method of fixing the cooling unit of the eighth embodiment in a tenth embodiment. FIG. 13 illustrates a state in which the cooling unit of the eighth embodiment is fixed to the ceiling wall 8 of the FFU chamber 5. The ceiling wall 8 of the wafer conveyance device E of the present embodiment is provided with an opening into which the cooling heat sink 9a is inserted and a screw hole 25 of a bolt 23 in order to fix the cooling unit to the ceiling wall 8. The flat plate 17 is provided with a through-hole 24 through which the bolt 23 passes.

The flat plate 17 is installed so as to cover the opening provided in the ceiling wall 8 from the outside, and the bolt 23 is inserted into the through-hole 24 and the screw hole 25 from the flat plate 17 side and tightened, whereby the flat plate 17 is fixed to the ceiling wall 8. As illustrated in FIG. 10A of the seventh embodiment, even when the Peltier element 13, the heat dissipation heat sink 14, and the cooling fan 15 are provided in the electrical compartment 16, the cooling unit can be similarly fixed.

### Eleventh Embodiment

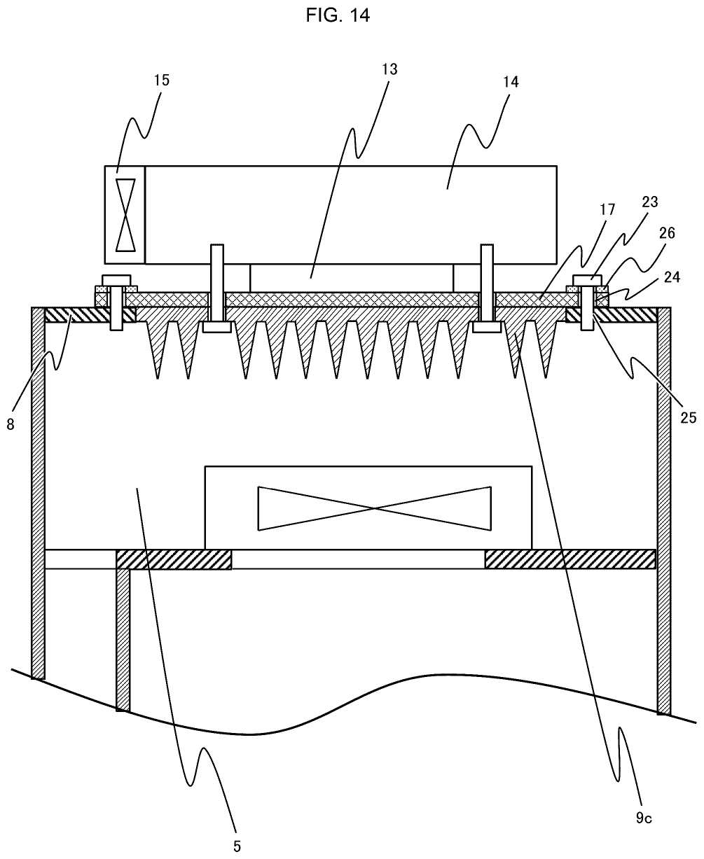

FIG. 14 is a diagram for explaining another example of the method of fixing the cooling unit of the eighth embodiment from the tenth embodiment. In addition to the configuration of the tenth embodiment, the wafer conveyance device E of the present embodiment includes a material having high thermal resistance, for example, a resin material 26 sandwiched between the head of the bolt 23 fixing the cooling unit and the flat plate 17. This makes it possible to prevent heat from the outside from being transferred to the flat plate 17 via the bolt 23.

### Twelfth Embodiment

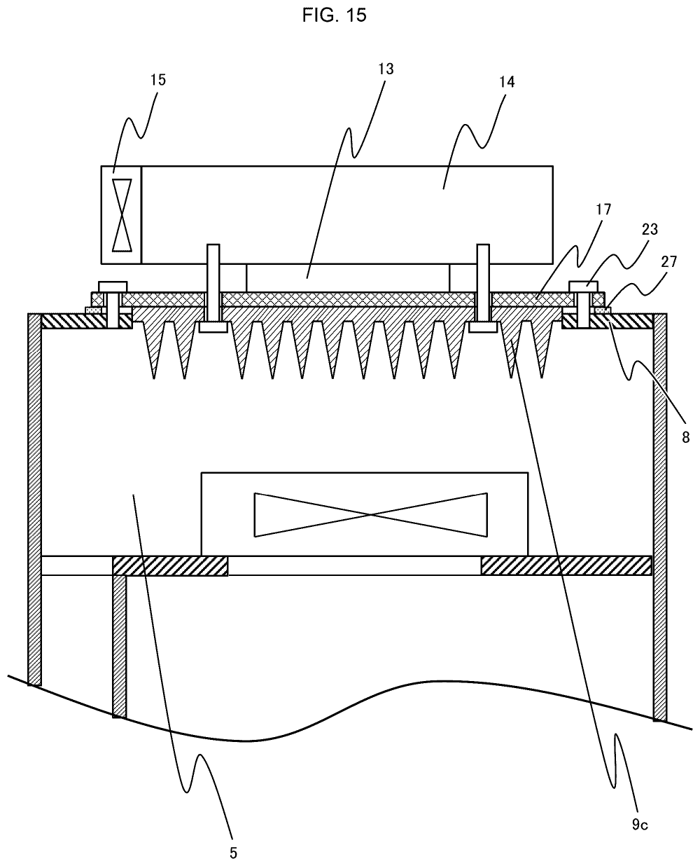

FIG. 15 is a diagram for explaining another example of the method of fixing the cooling unit of the eighth embodiment from tenth and eleventh embodiments. The wafer conveyance device E of the present embodiment includes a sealing material 27 between the flat plate 17 and the ceiling wall 8 in addition to the configuration of the tenth embodiment. By providing the sealing material 27, the internal space of the wafer conveyance device E can be sealed, and the gas can be prevented from entering and exiting.

### REFERENCE SIGNS LIST

E wafer conveyance device
P column
D door
1 wafer conveyance chamber
2 FOUP
3 processing device
4 conveyance robot
5 FFU chamber
6 FFU (Fan Filter Unit)
7 return duct
8 ceiling wall
9a cooling heat sink
9b integrated structure of cooling heat sink and ceiling wall
9c cooling heat sink
10 wall of return duct
11 wafer conveyance chamber wall
12 cold water pipe
13 Peltier element
14 heat dissipation heat sink
15 cooling fan
16 electrical compartment
17 flat plate
18 bolt
19 through-hole
20 through-hole
21 screw hole
22 washer
23 bolt
24 through-hole
25 screw hole
26 washer
27 sealing material

1. A wafer conveyance device for conveying a wafer between a FOUP (Front-Opening Unified Pod) in which the wafer is stored and a processing device for processing the wafer, the wafer conveyance device comprising:
a wafer conveyance chamber in which a conveyance robot is installed;
an FFU chamber communicating with the wafer conveyance chamber;
a return duct provided in a wall or a door of the wafer conveyance chamber and communicating with both the wafer conveyance chamber and the FFU room;
a blowing fan that blows gas from the FFU chamber into the wafer conveyance chamber; and
a heat exchanger that cools the gas circulating in an internal space including the FFU chamber, the return duct, and the wafer conveyance chamber.

2. The wafer conveyance device according to claim 1, wherein the heat exchanger includes:
a cooling heat sink provided in an outer wall of the internal space and in contact with the gas; and
a cold water pipe that cools the cooling heat sink.

3. The wafer conveyance device according to claim 1, wherein the heat exchanger includes:
a cooling heat sink provided in an outer wall of the internal space and in contact with the gas; and
a Peltier element that is provided on a heat dissipation surface of the cooling heat sink and cools the cooling heat sink.

4. The wafer conveyance device according to claim 3, wherein the heat exchanger includes:
a heat dissipation heat sink that dissipates heat of a high-temperature surface of the Peltier element; and
a cooling fan that cools the heat dissipation heat sink.

5. The wafer conveyance device according to claim 4, comprising an electric compartment in which electric components are accommodated,
wherein the cooling heat sink is provided in the FFU chamber, and
the Peltier element, the heat dissipation heat sink, and the cooling fan are provided in the electric compartment.

6. The wafer conveyance device according to claim 4, comprising a flat plate sandwiched between the cooling heat sink and a low-temperature surface of the Peltier element,
wherein the cooling heat sink, the flat plate, and the heat dissipation heat sink are integrally fixed by a bolt inserted from a side of the cooling heat sink.

7. The wafer conveyance device according to claim 6, comprising a resin material sandwiched between a head of the bolt and the cooling heat sink.

8. The wafer conveyance device according to claim 6, comprising an opening that is provided in a part of an outer wall of the internal space and into which the cooling heat sink is inserted,
wherein the flat plate is installed so as to cover the opening from an outside, and is fixed to the outer wall with a bolt inserted from the outside.

9. The wafer conveyance device according to claim 8, comprising a resin material sandwiched between a head of the bolt and the flat plate.

10. The wafer conveyance device according to claim 8, comprising a sealing material sandwiched between the outer wall and the flat plate.

11. The wafer conveyance device according to claim 2, wherein the cooling heat sink is installed in a ceiling of the FFU chamber.

12. The wafer conveyance device according to claim 2, wherein the cooling heat sink is installed in a wall of the wafer conveyance chamber.

13. The wafer conveyance device according to claim 2, wherein the cooling heat sink is installed in a wall of the return duct.
